(19) United States
(12) Patent Application Publication
(10) Pub. No.: US 2026/0162607 A1
(43) Pub. Date: Jun. 11, 2026

(54) PIXEL CIRCUIT, DISPLAY DEVICE INCLUDING THE SAME, AND AN ELECTRONIC DEVICE INCLUDING THE DISPLAY DEVICE

(71) Applicant: Samsung Display Co., Ltd., Yongin-si (KR)

(72) Inventors: MIN CHUL SHIN, Yongin-si (KR); SUNG HWAN KIM, Yongin-si (KR); JIYOUN SEO, Yongin-si (KR); HYOUNG-RAE LEE, Yongin-si (KR); EUNBUM PYUN, Yongin-si (KR); JUNGHWAN HWANG, Yongin-si (KR)

(21) Appl. No.: 19/182,253

(22) Filed: Apr. 17, 2025

(30) Foreign Application Priority Data
Apr. 23, 2024 (KR) 10-2024-0054124

(51) Int. Cl. G09G 3/3233; G09G 3/36

(52) U.S. Cl. CPC G09G 3/3233; G09G 3/3648; G09G 2300/0819; G09G 2300/0852; G09G 2300/0861; G09G 2310/08; G09G 2320/045; G09G 2380/10

(57) ABSTRACT

A pixel circuit includes a light emitting element, a driving transistor configured to apply a driving current to the light emitting element, a storage capacitor including a first electrode connected to a gate electrode of the driving transistor and a second electrode, and a boost capacitor including a first electrode receiving a gate control signal and a second electrode connected to the gate electrode of the driving transistor. The gate control signal is changed from a first level to a second level at a starting point of a boosting period in a non-emission period, and is changed from the second level to the first level at an ending point of the boosting period.

### CROSS-REFERENCE TO RELATED APPLICATION

The present application claims priority to and the benefit of Korean Patent Application No. 10-2024-0054124, filed on Apr. 23, 2024, in the Korean Intellectual Property Office, the entire disclosure of which is incorporated by reference herein.

### BACKGROUND

### 1. Field

The present disclosure relates to a pixel circuit, a display device including the same, and an electronic device including the display device. More particularly, the present disclosure relates to a pixel circuit and a display device including the same for preventing a deterioration of a driving transistor.

### 2. Description of the Related Art

In general, a display device includes a display panel and a display panel driver. The display panel includes gate lines, data lines, emission lines, and pixel circuits. The display panel driver includes a gate driver for providing gate signals to the gate lines, a data driver for providing data voltages to the data lines, an emission driver for providing emission signals to the emission lines, and a driving controller for controlling the gate driver, the data driver, and the emission driver.

The pixel circuit may include a light emitting element and a driving transistor. The driving transistor may be turned on based on a voltage of a gate electrode of the driving transistor to apply a driving current to the light emitting element. The light emitting element may emit a light based on the driving current. The driving transistor may be deteriorated as the driving transistor is turned on and used.

Even in a non-emission period where the driving current does not flow to the light emitting element and the light emitting element does not emit a light, the driving transistor may be turned on based on the voltage of the gate electrode of the driving transistor, and thus the driving transistor may be deteriorated.

### SUMMARY

Embodiments of the present disclosure provide a pixel circuit for preventing a deterioration of a driving transistor.

Embodiments of the present disclosure provide a display device including the pixel circuit.

In one or more embodiments of the present disclosure, a pixel circuit includes a light emitting element, a driving transistor configured to apply a driving current to the light emitting element, a storage capacitor including a first electrode connected to a gate electrode of the driving transistor and a second electrode, and a boost capacitor including a first electrode receiving a gate control signal and a second electrode connected to the gate electrode of the driving transistor. The gate control signal is changed from a first level to a second level at a starting point of a boosting period in a non-emission period, and is changed from the second level to the first level at an ending point of the boosting period.

In one or more embodiments, when the gate control signal is changed from the first level to the second level, a voltage of the gate electrode of the driving transistor may be changed by a boosting voltage corresponding to a difference between the first level and the second level, and the driving transistor may be turned off based on a threshold voltage of the driving transistor.

In one or more embodiments, when the gate control signal is changed from the first level to the second level or from the second level to the first level, a voltage of the gate electrode of the driving transistor may be changed by the boosting voltage.

In one or more embodiments, a voltage of the gate electrode of the driving transistor immediately before the starting point of the boosting period may be equal to a voltage of the gate electrode of the driving transistor immediately after the ending point of the boosting period.

In one or more embodiments, when the driving transistor is a P-type transistor, the first level may be lower than the second level.

In one or more embodiments, when the gate control signal is changed from the first level to the second level, the voltage of the gate electrode of the driving transistor may increase by the boosting voltage.

In one or more embodiments, when the gate control signal is changed from the second level to the first level, the voltage of the gate electrode of the driving transistor may decrease by the boosting voltage.

In one or more embodiments, the driving transistor may include the gate electrode connected to a gate node, a first electrode connected to a first node, and a second electrode connected to a second node, the storage capacitor may include the first electrode connected to the gate node and the second electrode configured to receive a first driving voltage, the boost capacitor may include the first electrode configured to receive the gate control signal and the second electrode connected to the gate node, and the light emitting element may include an anode electrode and a cathode electrode configured to receive a second driving voltage.

In one or more embodiments, the pixel circuit further include a data write transistor including a gate electrode configured to receive a data write gate signal, a first electrode configured to receive a data voltage, and a second electrode connected to the first node, a compensation transistor including a gate electrode configured to receive the data write gate signal, a first electrode connected to the second node, and a second electrode connected to the gate node, a data initialization transistor including a gate electrode configured to receive a data initialization gate signal, a first electrode configured to receive an initialization voltage, and a second electrode connected to the gate node, a first emission transistor including a gate electrode configured to receive an emission signal, a first electrode configured to receive the first driving voltage, and a second electrode connected to the first node, a second emission transistor including a gate electrode configured to receive the emission signal, a first electrode connected to the second node, and a second electrode connected to the anode electrode, and an anode initialization transistor including a gate electrode configured to receive an anode initialization gate signal, a first electrode configured to receive the initialization voltage, and a second electrode connected to the anode electrode.

In one or more embodiments, the non-emission period may not include a turn-on voltage period of the emission signal, and an emission period may include the turn-on voltage period of the emission signal.

In one or more embodiments, a non-boosting period in the non-emission period may include a turn-on voltage period of the data write gate signal, a turn-on voltage period of the data initialization gate signal, a turn-on voltage period of the emission signal, and a turn-on voltage period of the anode initialization gate signal.

In one or more embodiments, when the driving transistor is an N-type transistor, the first level may be higher than the second level.

In one or more embodiments, when the gate control signal is changed from the first level to the second level, the voltage of the gate electrode of the driving transistor may decrease by the boosting voltage.

In one or more embodiments, when the gate control signal is changed from the second level to the first level, the voltage of the gate electrode of the driving transistor may increase by the boosting voltage.

In one or more embodiments, the driving transistor may include the gate electrode connected to a gate node, a first electrode connected to a first node, a second electrode connected to a second node, and a back gate electrode connected to the second node, the storage capacitor may include the first electrode connected to the gate node and the second electrode connected to the second node, the boost capacitor may include the first electrode configured to receive the gate control signal and the second electrode connected to the gate node, and the light emitting element may include an anode electrode and a cathode electrode configured to receive a second driving voltage.

In one or more embodiments, the pixel circuit further include a data write transistor including a gate electrode configured to receive a data write gate signal, a first electrode configured to receive a data voltage, and a second electrode connected to the gate node, a reference voltage transistor including a gate electrode configured to receive a reference voltage gate signal, a first electrode configured to receive a reference voltage, and a second electrode connected to the gate node, an anode initialization transistor including a gate electrode configured to receive an anode initialization gate signal, a first electrode configured to receive an initialization voltage, and a second electrode connected to the anode electrode, an emission transistor including gate electrode configured to receive an emission gate signal, a first electrode configured to receive a first driving voltage, and a second electrode connected to the first node, and a hold capacitor including a first electrode configured to receive the first driving voltage and a second electrode connected to the second node.

In one or more embodiments, an emission period may include a turn-on voltage period of the emission gate signal.

In one or more embodiments, a non-boosting period in the non-emission period may include a turn-on voltage period of the data write gate signal, a turn-on voltage period of the reference voltage gate signal, a turn-on voltage period of the anode initialization gate signal, and a turn-on voltage period of the emission gate signal.

In one or more embodiments of a display device according to the present inventive concept, the display device includes a display panel including a pixel circuit and a display panel driver configured to drive the display panel. The pixel circuit includes a light emitting element, a driving transistor configured to apply a driving current to the light emitting element, a storage capacitor including a first electrode connected to a gate electrode of the driving transistor and a second electrode, and a boost capacitor including a first electrode configured to receive a gate control signal and a second electrode connected to the gate electrode of the driving transistor. The gate control signal is changed from a first level to a second level at a starting point of a boosting period in a non-emission period, and is changed from the second level to the first level at an ending point of the boosting period.

In one or more embodiments, when the gate control signal is changed from the first level to the second level, a voltage of the gate electrode of the driving transistor may be changed by a boosting voltage corresponding to a difference between the first level and the second level, and the driving transistor is turned off based on a threshold voltage of the driving transistor.

In one or more embodiments, an electronic device including a display device, the display device includes: a display panel including a pixel circuit; and a display panel driver configured to drive the display panel, wherein the pixel circuit includes: a light emitting element; a driving transistor configured to apply a driving current to the light emitting element; a storage capacitor including a first electrode connected to a gate electrode of the driving transistor and a second electrode; and a boost capacitor including a first electrode configured to receive a gate control signal and a second electrode connected to the gate electrode of the driving transistor, wherein the gate control signal is changed from a first level to a second level at a starting point of a boosting period in a non-emission period, and is changed from the second level to the first level at an ending point of the boosting period, and wherein, when the driving transistor is a P-type transistor, the first level is lower than the second level.

The electronic device includes a cellular phone, a video phone, a smart pad, a smart watch, a tablet PC, a car navigation system, a computer monitor, a laptop, or a head mounted display (HMD) device.

According to the pixel circuit and the display device including the pixel circuit, the pixel circuit may include the boost capacitor including the first electrode configured to receive the gate control signal and the second electrode connected to the gate electrode of the driving transistor. The voltage of the gate electrode of the driving transistor may be changed based on the gate control signal in the boosting period in the non-emitting period, and the driving transistor may be turned off in the boosting period. Accordingly, the deterioration of the driving transistor may be prevented.

### BRIEF DESCRIPTION OF THE DRAWINGS

The above and other features of the present disclosure will become more apparent by describing in detailed embodiments thereof with reference to the accompanying drawings, in which:

FIG. 1 is a block diagram showing a display device according to one or more embodiments of the present disclosure;

FIG. 2 is a circuit diagram showing an example of a pixel circuit of FIG. 1;

FIG. 3 is a timing diagram showing gate signals, an emission signal, and a gate control signal of the pixel circuit of FIG. 2;

FIG. 4A is a circuit diagram showing the pixel circuit of FIG. 2 operating in a first time period of FIG. 3;

FIG. 4B is a circuit diagram showing the pixel circuit of FIG. 2 operating in a second time period of FIG. 3;

FIG. 4C is a circuit diagram showing the pixel circuit of FIG. 2 operating in an emission period of FIG. 3;

FIG. 4D is a circuit diagram showing the pixel circuit of FIG. 2 operating at a starting point of a boosting period of FIG. 3;

FIG. 4E is a circuit diagram showing the pixel circuit of FIG. 2 operating at an ending point of a boosting period of FIG. 3;

FIG. 5 is a circuit diagram showing an example of a pixel circuit of FIG. 1;

FIG. 6 is a timing diagram showing gate signals and a gate control signal of the pixel circuit of FIG. 5;

FIG. 7A is a circuit diagram showing the pixel circuit of FIG. 5 operating in a first time period of FIG. 6;

FIG. 7B is a circuit diagram showing the pixel circuit of FIG. 5 operating in a second time period of FIG. 6;

FIG. 7C is a circuit diagram showing the pixel circuit of FIG. 5 operating in a third time period of FIG. 6;

FIG. 7D is a circuit diagram showing the pixel circuit of FIG. 5 operating in a fourth time period of FIG. 6;

FIG. 7E is a circuit diagram showing the pixel circuit of FIG. 5 operating in an emission period of FIG. 6;

FIG. 7F is a circuit diagram showing the pixel circuit of FIG. 5 operating at a starting point of a boosting period of FIG. 6;

FIG. 7G is a circuit diagram showing the pixel circuit of FIG. 5 operating at an ending point′ of a boosting period BP′ of FIG. 6;

FIG. 8 is a block diagram showing an electronic device; and

FIG. 9 is a diagram showing an embodiment in which an electronic device of FIG. 8 is implemented as a smart phone.

### DETAILED DESCRIPTION

Hereinafter, the present disclosure will be described in more detail with reference to the accompanying drawings.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

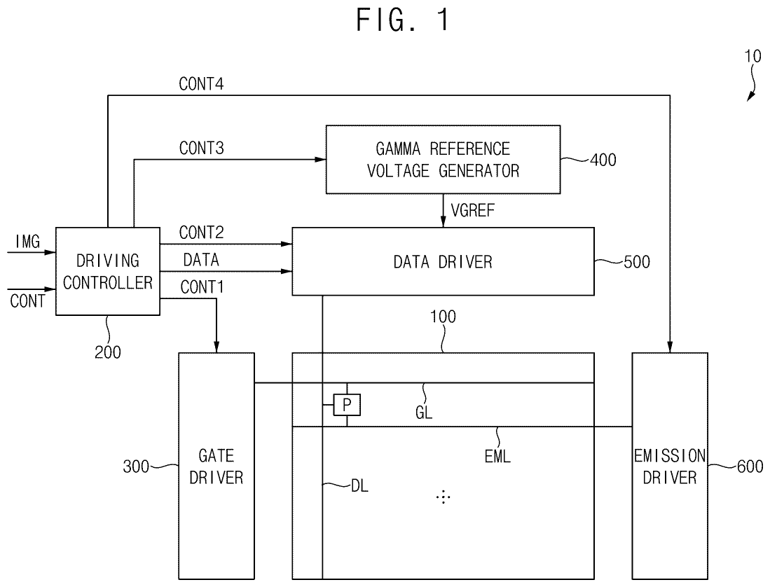

FIG. 1 is a block diagram showing a display device 10 according to one or more embodiments of the present disclosure.

Referring to FIG. 1, a display device 10 may include a display panel 100 and a display panel driver. The display panel driver may include a driving controller 200, a gate driver 300, a gamma reference voltage generator 400, a data driver 500, and an emission driver 600.

For example, the driving controller 200 and the data driver 500 may be formed integrally. For example, the driving controller 200, the gamma reference voltage generator 400, and the data driver 500 may be formed integrally. For example, the driving controller 200, the gate driver 300, the gamma reference voltage generator 400, and the data driver 500 may be formed integrally. For example, the driving controller 200, the gate driver 300, the gamma reference voltage generator 400, the data driver 500, and the emission driver 600 may be formed integrally. In one or more embodiments, a driving module in which at least the driving controller 200 and the data driver 500 are formed integrally may be referred to as a timing controller embedded data driver (TED).

The display panel 100 may include a display region for displaying an image and a peripheral region disposed adjacent to the display region.

For example, the display panel 100 may be an organic light emitting diode (OLED) display panel including an organic light emitting diode (OLED). For another example, the display panel 100 may be a quantum dot organic light emitting diode display panel including an organic light emitting diode (OLED) and a quantum dot (QD) color filter. For another example, the display panel 100 may be a quantum dot nano light emitting diode display panel including a nano light emitting diode and a quantum dot color filter. For another example, the display panel 100 may be a liquid crystal display panel including a liquid crystal layer.

The display panel 100 may include gate lines GL, data lines DL, emission lines EML and pixel circuits P electrically connected to the gate lines GL, the data lines DL, and the emission lines EML, respectively. The gate lines GL may extend in a first direction, the data lines DL may extend in a second direction crossing the first direction, and the emission lines EML may extend in the first direction.

The driving controller 200 may receive input image data IMG and an input control signal CONT from an external device. For example, the input image data IMG may include red image data, green image data, and blue image data. The input image data IMG may include white image data. The input image data IMG may include magenta image data, yellow image data, and cyan image data. The input control signal CONT may include a master clock signal and a data enable signal. The input control signal CONT may further include a vertical synchronization signal and a horizontal synchronization signal.

The driving controller 200 may generate a first control signal CONT1, a second control signal CONT2, a third control signal CONT3, a fourth control signal CONT4, and a data signal DATA based on the input image data IMG and the input control signal CONT.

The driving controller 200 may generate the first control signal CONT1 for controlling an operation of the gate driver 300 based on the input control signal CONT, and output the first control signal CONT1 to the gate driver 300. The first control signal CONT1 may include a vertical start signal and a gate clock signal.

The driving controller 200 may generate the second control signal CONT2 for controlling an operation of the data driver 500 based on the input control signal CONT, and output the second control signal CONT2 to the data driver 500. The second control signal CONT2 may include a horizontal start signal and a load signal.

The driving controller 200 may generate the data signal DATA based on the input image data IMG. The driving controller 200 may output the data signal DATA to the data driver 500.

The driving controller 200 may generate the third control signal CONT3 for controlling an operation of the gamma reference voltage generator 400 based on the input control signal CONT, and output the third control signal CONT3 to the gamma reference voltage generator 400.

The driving controller 200 may generate the fourth control signal CONT4 for controlling an operation of the emission driver 600 based on the input control signal CONT, and output the fourth control signal CONT4 to the emission driver 600.

The gate driver 300 may generate gate signals for driving the gate lines GL in response to the first control signal CONT1 received from the driving controller 200. The gate driver 300 may output the gate signals to the gate lines GL.

In one or more embodiments, the gate driver 300 may be integrated in the periphery region of the display panel 100.

The gamma reference voltage generator 400 may generate a gamma reference voltage VGREF in response to the third control signal CONT3 received from the driving controller 200. The gamma reference voltage generator 400 may provide the gamma reference voltage VGREF to the data driver 500. The gamma reference voltage VGREF may have a value corresponding to each data signal DATA.

For example, the gamma reference voltage generator 400 may be disposed in the driving controller 200 or may be disposed in the data driver 500.

The data driver 500 may receive the second control signal CONT2 and the data signal DATA from the driving controller 200, and receive the gamma reference voltage VGREF from the gamma reference voltage generator 400. The data driver 500 may convert the data signal DATA into a data voltage having an analog type using the gamma reference voltage VGREF. The data driver 500 may output the data voltage to the data line DL.

The emission driver 600 may generate emission signals for driving the emission lines EML in response to the fourth control signal CONT4 received from the driving controller 200. The emission driver 600 may output the emission signals to the emission lines EML.

In one or more embodiments, the emission driver 600 may be integrated into the peripheral region of the display panel 100. In one or more embodiments, the emission driver 600 may be mounted into the peripheral region of the display panel 100.

In FIG. 1, for a convenience of an explanation, the gate driver 300 may be disposed on a first side of the display panel 100 and the emission driver 600 may be disposed on a second side of the display panel 100. Although shown, the present disclosure is not limited thereto. For example, both the gate driver 300 and the emission driver 600 may be disposed on the first side of the display panel 100. For example, both the gate driver 300 and the emission driver 600 may be disposed on both sides of the display panel 100. For example, the gate driver 300 and the emission driver 600 may be formed integrally.

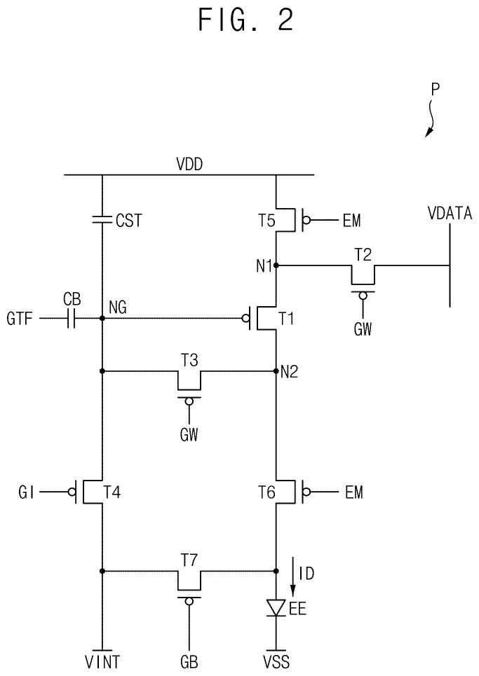

FIG. 2 is a circuit diagram showing an example of a pixel circuit P of FIG. 1.

Referring to FIG. 2, a pixel circuit P according to one or more embodiments of the present disclosure may include a light emitting element EE, a driving transistor T1, a storage capacitor CST, and a boost capacitor CB. The pixel circuit P may further include a data write transistor T2, a compensation transistor T3, a data initialization transistor T4, a first emission transistor T5, a second emission transistor T6, and an anode initialization transistor T7. In one or more embodiments, the driving transistor T1, the data write transistor T2, the compensation transistor T3, the data initialization transistor T4, the first emission transistor T5, the second emission transistor T6, and the anode initialization transistor T7 may be P-type transistors. When a voltage of a gate electrode of the P-type transistor has a low level, the P-type transistor may be turned on. When the voltage of the gate electrode of the P-type transistor has a high level, the P-type transistor may be turned off.

The driving transistor T1 may include a gate electrode connected to a gate node NG, a first electrode connected to a first node N1, and a second electrode connected to a second node N2.

The data write transistor T2 may include a gate electrode receiving a data write gate signal GW, a first electrode receiving a data voltage VDATA, and a second electrode connected to the first node N1.

The compensation transistor T3 may include a gate electrode receiving the data write gate signal GW, a first electrode connected to the second node N2, and a second electrode connected to the gate node NG.

The data initialization transistor T4 may include a gate electrode receiving a data initialization gate signal GI, a first electrode receiving an initialization voltage VINT, and a second electrode connected to the gate node NG.

The first emission transistor T5 may include a gate electrode receiving an emission signal EM, a first electrode receiving a first driving voltage VDD, and a second electrode connected to the first node N1.

The second emission transistor T6 may include a gate electrode receiving the emission signal EM, a first electrode connected to the second node N2, and a second electrode connected to an anode electrode of the light emitting element EE.

The anode initialization transistor T7 may include a gate electrode receiving an anode initialization gate signal GB, a first electrode receiving the initialization voltage VINT, and a second electrode connected to the anode electrode.

The storage capacitor CST may include the first electrode connected to the gate node NG and the second electrode receiving the first driving voltage VDD.

The boost capacitor CB may include a first electrode receiving a gate control signal GTF and a second electrode connected to the gate node.

The light emitting element EE may include an anode electrode and a cathode electrode receiving a second driving voltage VSS. For example, the light emitting element EE may be a micro light emitting diode (uLED), an organic light emitting diode (OLED), a nano-light emitting diode (NED), a quantum dot light emitting diode (QD), an inorganic light emitting diode, or any other suitable light emitting element.

The configuration of the pixel circuit P according to one or more embodiments of the present disclosure is not limited to the example illustrated in FIG. 2. FIG. 2 is the example for explaining the pixel circuit including the driving transistor T1, which is the P-type transistor. Therefore, the configuration of the pixel circuit P according to one or more embodiments of the present disclosure may have any configuration in which the driving transistor T1 is the P-type transistor.

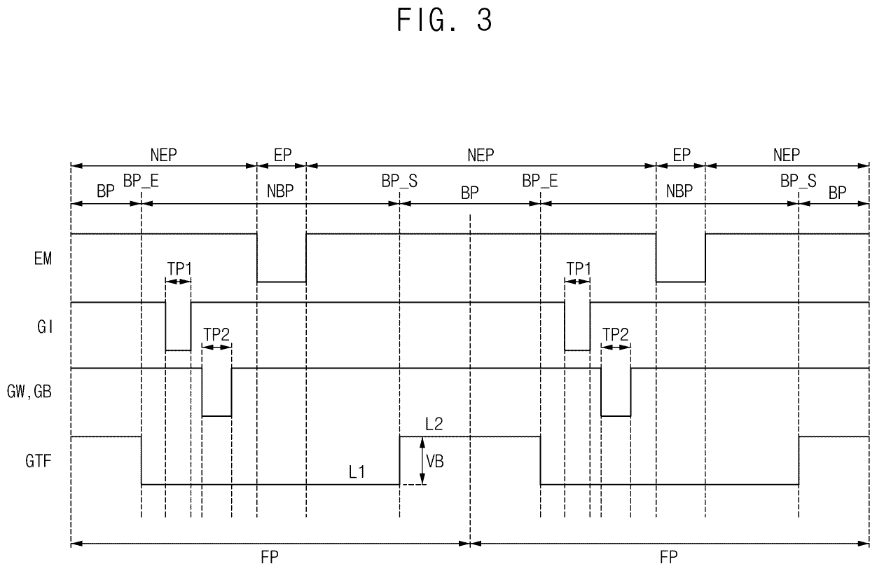

FIG. 3 is a timing diagram showing gate signals GW, GI, GB, an emission signal EM, and a gate control signal GTF of a pixel circuit P of FIG. 2.

Referring to FIG. 2 and FIG. 3, a frame period FP for the pixel circuit P may include an emission period EP and a non-emission period NEP. The non-emission period NEP may include a portion of a non-boosting period NBP and a boosting period BP. The non-boosting period NBP may include a first time period TP1 and a second time period TP2.

The emission period EP may include a turn-on voltage period of the emission signal EM, and the non-emission period NEP may not include a turn-on voltage period of the emission signal EM. The emission signal EM may have the low level in the emission period EP and may have the high level in the non-emission period NEP. The emission period EP may be a period in which the driving current ID flows to the light emitting element EE and the light emitting element EE emits light based on the driving current ID, and the non-emission period NEP may be a period in which the driving current ID does not flow to the light emitting element EE and the light emitting element EE does not emit a light based on the driving current ID.

The gate control signal GTF may have a first level L1 in the non-boosting period NBP, may be changed from the first level L1 to a second level L2 at a starting point BP_S of the boosting period BP, may have the second level L2 in the boosting period BP, and may be changed from the second level L2 to the first level L1 at an ending point BP_E of the boosting period BP. When the driving transistor T1 is the P-type transistor, the first level L1 may be lower than the second level L2. A voltage corresponding to a difference between the first level L1 and the second level L2 may be referred to as a boosting voltage VB. Here, the boosting voltage VB may be determined based on a voltage distribution of capacitors (e.g., a storage capacitor CST, a boost capacitor CB, and a parasitic capacitor) connected to the gate node NG. The non-boosting period NBP may be a period in which a voltage of the gate electrode of the driving transistor T1 is not boosted, and the boosting period BP may be a period in which the voltage of the gate electrode of the driving transistor T1 is boosted by the boosting voltage VB.

The non-boosting period NBP may include a turn-on voltage period of the data write gate signal GW, a turn-on voltage period of the data initialization gate signal GI, a turn-on voltage period of the emission signal EM, and a turn-on voltage period of the anode initialization gate signal GB.

The first time period TP1 may include the turn-on voltage period of the data initialization gate signal GI. The data initialization gate signal GI may have the low level in the first time period TP1 and may have the high level in a frame period FP excluding the first time period TP1.

The second time period TP2 may include the turn-on voltage period of the data write gate signal GW and the turn-on voltage period of the anode initialization gate signal GB. The data write gate signal GW and the anode initialization gate signal GB may have the low level in the second time period TP2 and may have the high level in a frame period FP excluding the second time period TP2.

In one or more embodiments, when the light emitting element EE is the micro light emitting diode, the emission signal EM may include a turn-on voltage period that does not overlap each other for each of the red sub-pixel, the green sub-pixel, and the blue sub-pixel.

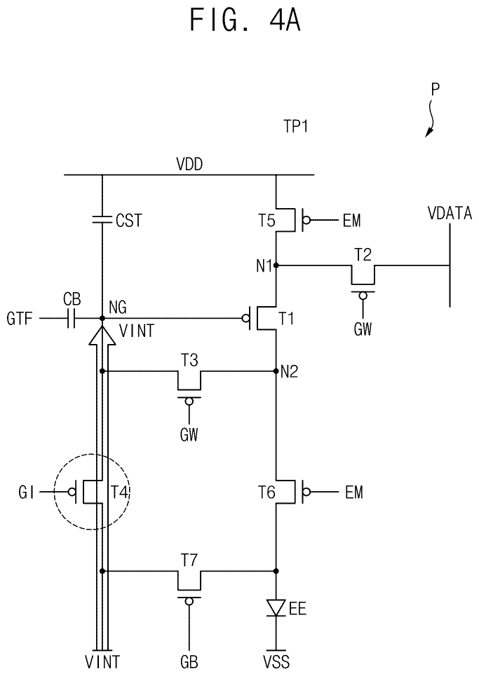

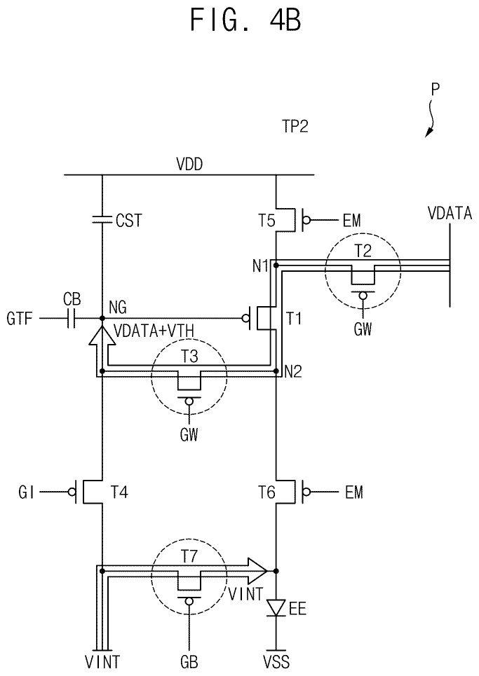

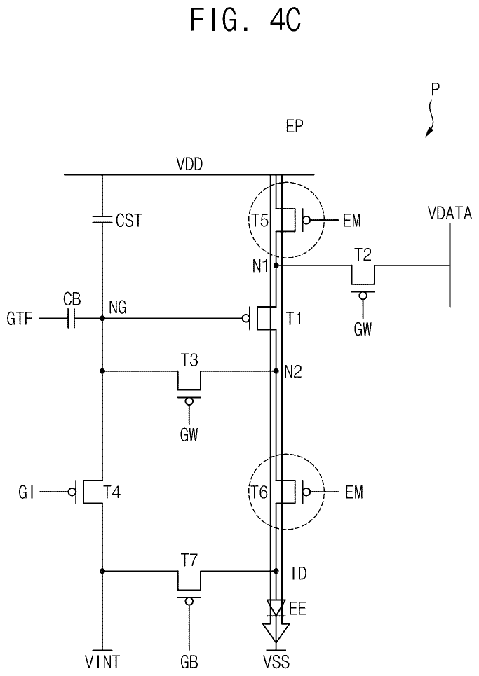

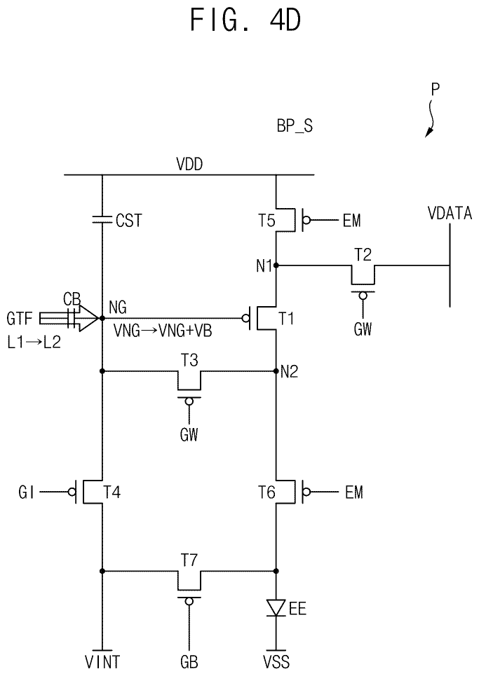

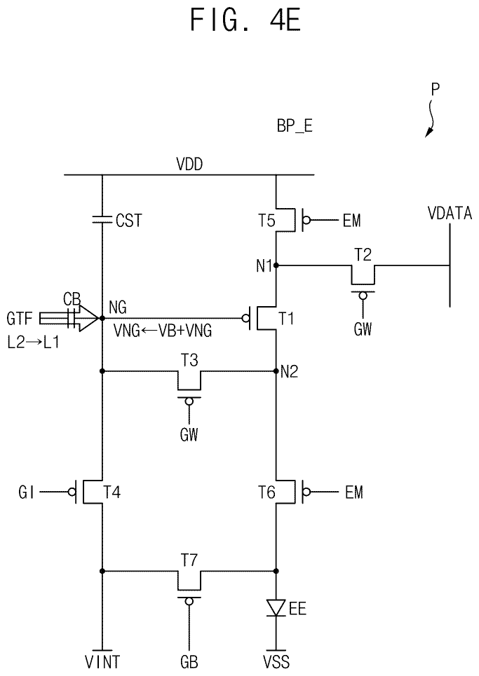

FIG. 4A is a circuit diagram showing the pixel circuit P of FIG. 2 operating in the first time period TP1 of FIG. 3.

Referring to FIG. 2-4A, the data initialization transistor T4 may be turned on in response to the data initialization gate signal GI having the low level. The data initialization transistor T4 may apply the initialization voltage VINT to the gate electrode of the driving transistor T1. Therefore, the gate electrode of the driving transistor T1 may be initialized with the initialization voltage VINT.

FIG. 4B is a circuit diagram showing the pixel circuit P of FIG. 2 operating in the second time period TP2 of FIG. 3.

Referring to FIG. 2-4B, the data write transistor T2 may be turned on in response to the data write gate signal GW having the low level, and the compensation transistor T3 may be turned on in response to the data write gate signal GW having the low level.

The data voltage VDATA may be applied to the second node N2 through the data write transistor T2 and the driving transistor T1. The compensation transistor T3 may diode-connect the driving transistor T1 to compensate for a threshold voltage VTH of the driving transistor T1, and may apply a voltage obtained by adding the threshold voltage VTH of the driving transistor T1 to the data voltage VDATA to the gate electrode of the driving transistor T1. That is, the voltage of the gate electrode of the driving transistor T1 may be VDATA+VTH. The storage capacitor CST may store the voltage of the gate electrode of the driving transistor T1.

The anode initialization transistor T7 may be turned on in response to the anode initialization gate signal GB having the low level. The anode initialization transistor T7 may apply the initialization voltage VINT to the anode electrode. Therefore, the anode electrode may be initialized with the initialization voltage VINT.

FIG. 4C is a circuit diagram showing the pixel circuit P of FIG. 2 operating in the emission period EP of FIG. 3.

Referring to FIG. 2-4C, the first emission transistor T5 may be turned on in response to the emission signal EM having the low level, and the second emission transistor T6 may be turned on in response to the emission signal EM having the low level.

The driving current ID may flow in an order of the first emission transistor T5, the driving transistor T1, and the second emission transistor T6 and may be applied to the light emitting element EE. The light emitting element EE may emit the light based on the driving current ID. An intensity of the driving current ID may be determined based on a level of the data voltage VDATA. A brightness of the light emitting element EE may be determined based on the intensity of the driving current ID.

FIG. 4D is a circuit diagram showing the pixel circuit P of FIG. 2 operating at the starting point BP_S of the boosting period BP of FIG. 3. FIG. 4E is a circuit diagram showing the pixel circuit P of FIG. 2 operating at the ending point BP_E of the boosting period BP of FIG. 3.

Referring to FIG. 2-4E, even in the non-emission period NEP in which the driving current ID does not flow to the light emitting element EE and thus the light emitting element EE does not emit the light, the driving transistor T1 may be turned on based on the voltage of the gate electrode of the driving transistor T1. This is because the storage capacitor CST stores a voltage corresponding to the data voltage VDATA. When the driving transistor T1 maintains a turned-on state, the driving transistor T1 may be further deteriorated. Therefore, the non-emission period NEP includes the boosting period BP, so that the deterioration of the driving transistor T1 may be prevented.

When the gate control signal GTF is changed from the first level L1 to the second level L2 at the starting point BP_S of the boosting period BP, the voltage of the gate electrode of the driving transistor T1 may increase by the boosting voltage VB by the boost capacitor CB. That is, the voltage of the gate electrode of the driving transistor T1 may increase from VNG to VNG+VB. When the voltage of the gate electrode of the driving transistor T1 increases by the boosting voltage VB, the driving transistor T1 may be turned off according to the voltage of the gate electrode of the driving transistor T1. When the voltage of the gate electrode of the driving transistor T1 is greater than the threshold voltage VTH of the driving transistor T1, the driving transistor T1 may be turned off. In order for the driving transistor T1 to be turned off, a magnitude of the boosting voltage VB may be sufficiently large.

In the boosting period BP, the gate control signal GTF may maintain the second level L2. Because the gate control signal GTF maintains the second level L2, the driving transistor T1 may maintain a turn-off state, and the deterioration of the driving transistor T1 may be prevented.

When the gate control signal GTF is changed from the second level L2 to the first level L1 at the ending point BP_E of the boosting period BP, the voltage of the gate electrode of the driving transistor T1 may decrease by the boosting voltage VB by the boost capacitor CB. That is, the voltage of the gate electrode of the driving transistor T1 may decrease from VNG+VB to VNG. When the voltage of the gate electrode of the driving transistor T1 decreases by the boosting voltage VB, the driving transistor T1 may be turned on.

Because the voltage of the gate electrode of the driving transistor T1 before (e.g., immediately before) the starting point BP_S of the boosting period BP is VNG and the voltage of the gate electrode of the driving transistor T1 after (e.g., immediately after) the ending point BP_E of the boosting period BP is VNG, the voltage of the gate electrode of the driving transistor T1 before (e.g., immediately before) the starting point BP_S of the boosting period BP may be equal to the voltage of the gate electrode of the driving transistor T1 after (e.g., immediately after) the ending point BP_E of the boosting period BP. Therefore, even if the frame period FP includes the boosting period BP, the voltage of the gate electrode of the driving transistor T1 may be the same based on the before and after the boosting period BP.

As such, the pixel circuit P may include the boost capacitor CB including the first electrode receiving the gate control signal GTF and the second electrode connected to the gate electrode of the driving transistor T1. The voltage of the gate electrode of the driving transistor T1 may be changed based on the gate control signal GTF in the boosting period BP included in the non-emitting period NEP, and the driving transistor T1 may be turned off in the boosting period BP. Accordingly, the deterioration of the driving transistor T1 may be prevented.

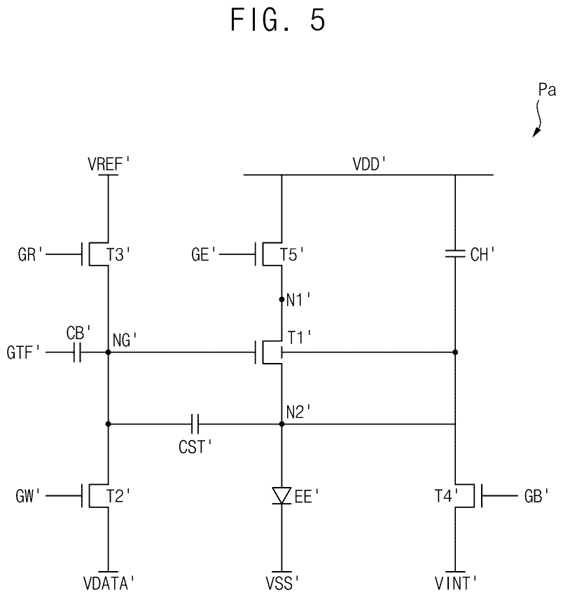

FIG. 5 is a circuit diagram showing an example of a pixel circuit Pa of FIG. 1.

Referring to FIG. 5, the pixel circuit Pa according to one or more embodiments of the present disclosure may include a light emitting element EE′, a driving transistor T1′, a storage capacitor CST′, and a boost capacitor CB′. The pixel circuit Pa may further include a data write transistor T2′, a reference voltage transistor T3′, an anode initialization transistor T4′, an emission transistor T5′, and a hold capacitor CH′. In one or more embodiments, the driving transistor T1′, the data write transistor T2′, the reference voltage transistor T3′, the anode initialization transistor T4′, and the emission transistor T5′ may be N-type transistors. When a voltage of a gate electrode of the N-type transistor has a high level, the N-type transistor may be turned on. When the voltage of the gate electrode of the N-type transistor has a low level, the N-type transistor may be turned off.

The driving transistor T1′ may include a gate electrode connected to a gate node NG′, a first electrode connected to a first node N1′, a second electrode connected to a second node N2′, and a back gate electrode connected to the second node N2′.

The data write transistor T2′ may include a gate electrode receiving a data write gate signal GW′, a first electrode receiving a data voltage VDATA′, and a second electrode connected to the gate node NG′.

The reference voltage transistor T3′ may include a gate electrode receiving a reference voltage gate signal GR′, a first electrode receiving a reference voltage VREF′, and a second electrode connected to the gate node NG′.

The anode initialization transistor T4′ may include a gate electrode receiving an anode initialization gate signal GB′, a first electrode receiving an initialization voltage VINT′, and a second electrode connected to an anode electrode of the light emitting element EE′.

The emission transistor T5′ may include a gate electrode receiving an emission gate signal GE′, a first electrode receiving a first driving voltage VDD′, and a second electrode connected to the first node N1′.

The storage capacitor CST′ may include the first electrode connected to the gate node NG′ and the second electrode connected to the second node N2′.

The boost capacitor CB′ may include the first electrode receiving a gate control signal GTF′ and the second electrode connected to the gate node NG′.

The hold capacitor CH′ may include a first electrode receiving the first driving voltage VDD′ and a second electrode connected to the second node N2′.

Because the back gate electrode of the driving transistor T1′ and the hold capacitor CH′ are connected to the second node N2′, a voltage of the back gate electrode of the driving transistor T1′ may be controlled. Therefore, a body effect in which a threshold voltage of the driving transistor T1′ is changed may be reduced or minimized. That is, a threshold voltage compensation capability of the pixel circuit Pa may be improved.

The light emitting element EE′ may include the anode electrode and a cathode electrode receiving the second driving voltage VSS′. For example, the light emitting element EE′ may be a micro light emitting diode (uLED), an organic light emitting diode (OLED), a nano light emitting diode (NED), a quantum dot light emitting diode (QD), an inorganic light emitting diode, or any other suitable light emitting element.

The configuration of the pixel circuit Pa according to one or more embodiments of the present disclosure is not limited to the example illustrated in FIG. 5. FIG. 5 is the example for explaining the pixel circuit including the driving transistor T1′ which is the N-type transistor. The configuration of the pixel circuit Pa according to one or more embodiments of the present one or more may have any configuration in which the driving transistor T1′ is the N-type transistor.

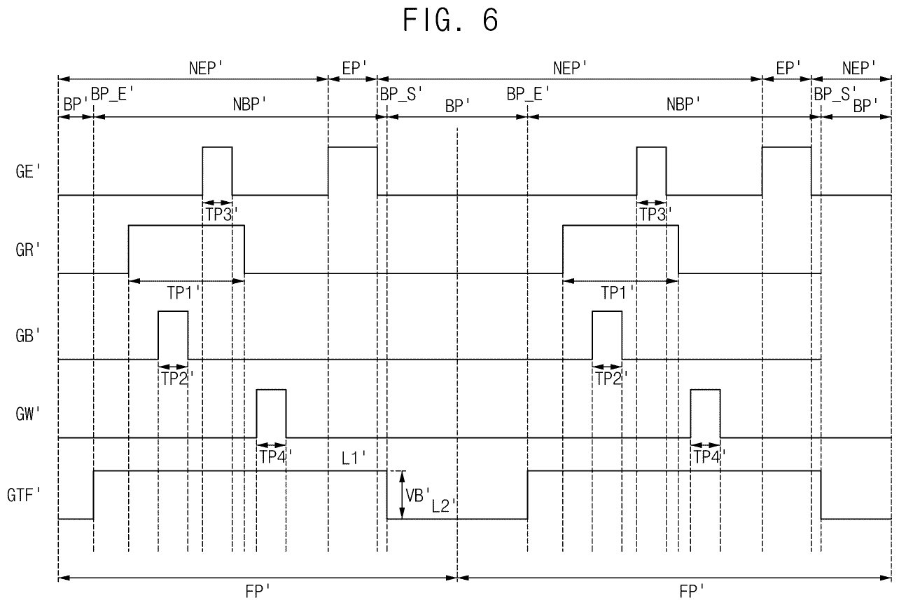

FIG. 6 is a timing diagram showing gate signals GW′, GR′, GB′, GE′ and a gate control signal GTF′ of a pixel circuit Pa of FIG. 5.

Referring to FIG. 5 and FIG. 6, a frame period FP′ for the pixel circuit Pa may include an emission period EP′ and a non-emission period NEP′. The non-emission period NEP′ may include a portion of a non-boosting period NBP′ and a boosting period BP′. The non-boosting period NBP′ may include a first time period TP1′, a second time period TP2′, a third time period TP3′, and a fourth time period TP4′.

The emission period EP′ may include a turn-on voltage period of the emission gate signal GE′. The emission gate signal GE′ may have the high level in the emission period EP′. The emission period EP′ may be a period in which the driving current ID′ flows to the light emitting element EE′ and the light emitting element EE′ emits a light based on the driving current ID′, and the non-emission period NEP′ may be a period in which the driving current ID′ does not flow to the light emitting element EE′ and the light emitting element EE′ does not emit the light based on the driving current ID′.

The gate control signal GTF′ may have a first level L1′ in the non-boosting period NBP′, may be changed from the first level L1′ to a second level L2′ at a starting point BP_S′ of the boosting period BP′, may have the second level L2′ in the boosting period BP′, and may be changed from the second level L2′ to the first level L1′ at an ending point BP_E′ of the boosting period BP′. When the driving transistor T1′ is the N-type transistor, the first level L1′ may be higher than the second level L2′. A difference between the first level L1′ and the second level L2′ may be referred to as a boosting voltage VB′. The non-boosting period NBP′ may be a period in which a voltage of the gate electrode of the driving transistor T1′ is not boosted, and the boosting period BP′ may be a period in which the voltage of the gate electrode of the driving transistor T1′ is boosted by the boosting voltage VB′.

The non-boosting period NBP′ may include a turn-on voltage period of the data write gate signal GW′, a turn-on voltage period of the reference voltage gate signal GR′, a turn-on voltage period of the anode initialization gate signal GB′, and a turn-on voltage period of the emission gate signal GE′.

The first time period TP1′ may include the second time period TP2′ and the third time period TP3′. The first time period TP1′ may include the turn-on voltage period of the reference voltage gate signal GR′. The reference voltage gate signal GR′ may have the high level in the first time period TP1′ and may have the low level in a frame period FP′ excluding the first time period TP1′.

The second time period TP2′ may include the turn-on voltage period of the anode initialization gate signal GB′. The anode initialization gate signal GB′ may have the high level in the second time period TP2′ and may have the low level in a frame period FP′ excluding the second time period TP2′.

The third time period TP3′ may include the turn-on voltage period of the emission gate signal GE′. The emission gate signal GE′ may have the high level in the third time period TP3′ and may have the low level in a frame period FP′ excluding the third time period TP3′.

The fourth time period TP4′ may include the turn-on voltage period of the data write gate signal GW′. The data write gate signal GW′ may have the high level in the fourth time period TP4′ and may have the low level in a frame period FP′ excluding the fourth time period TP4′.

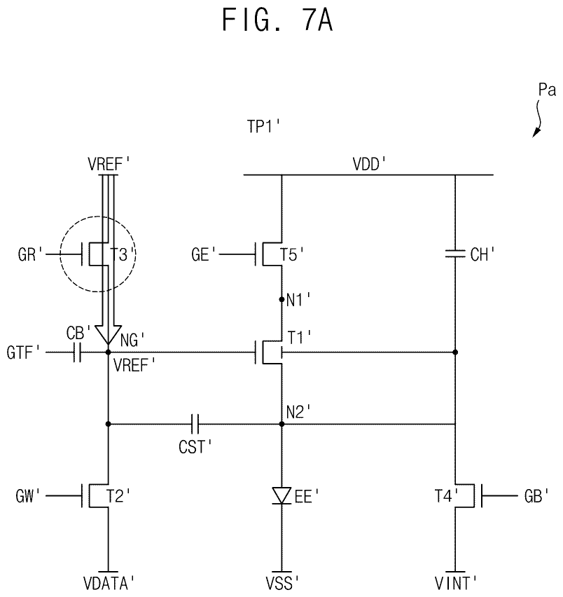

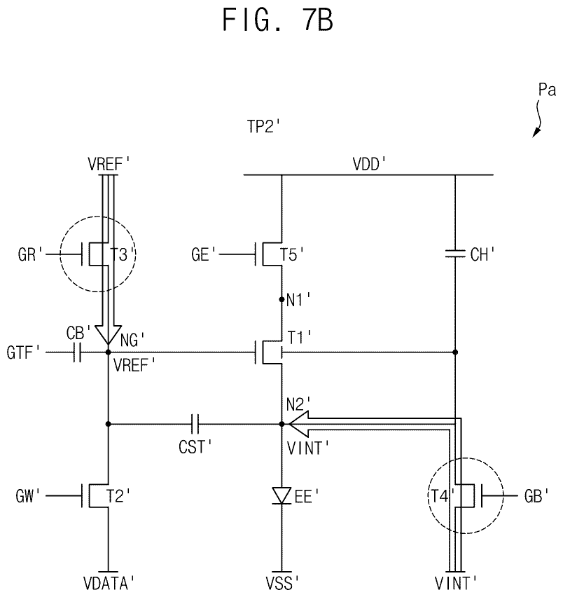

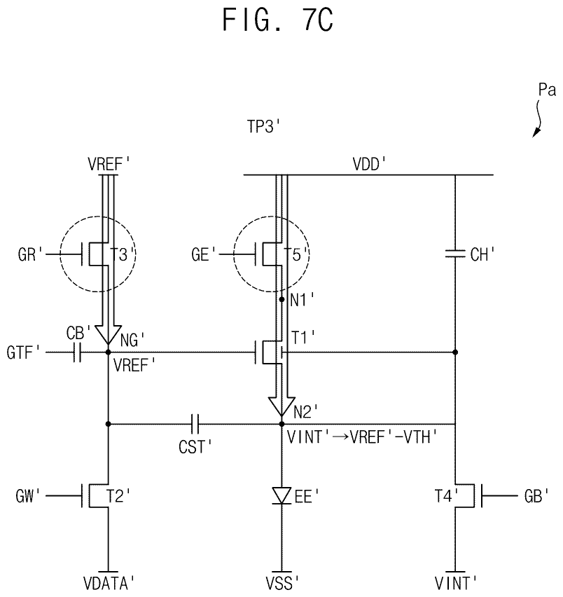

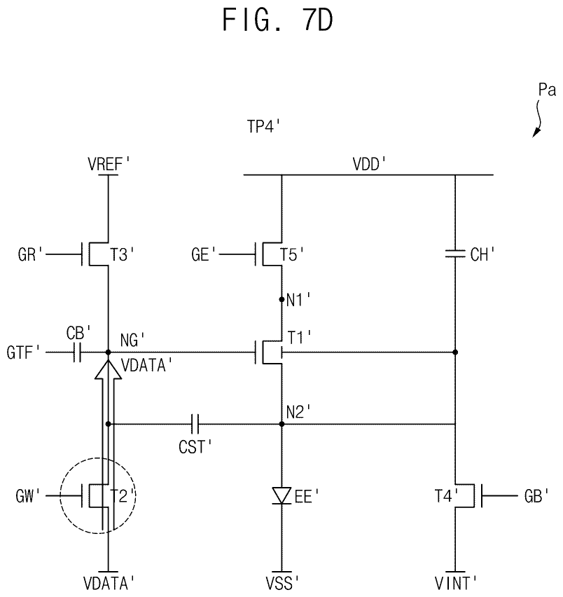

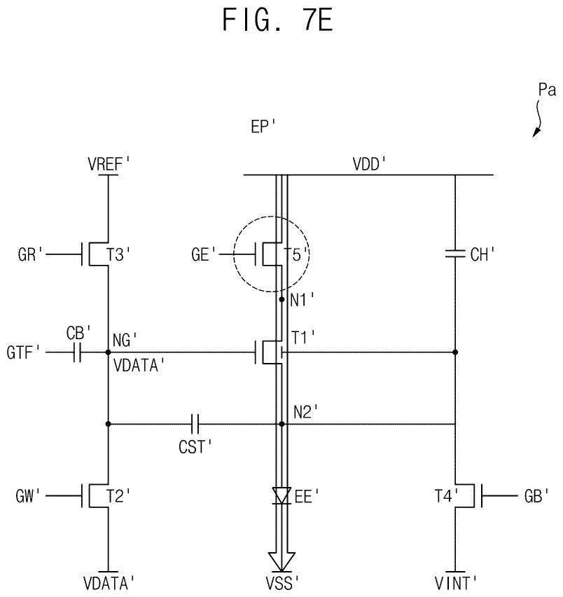

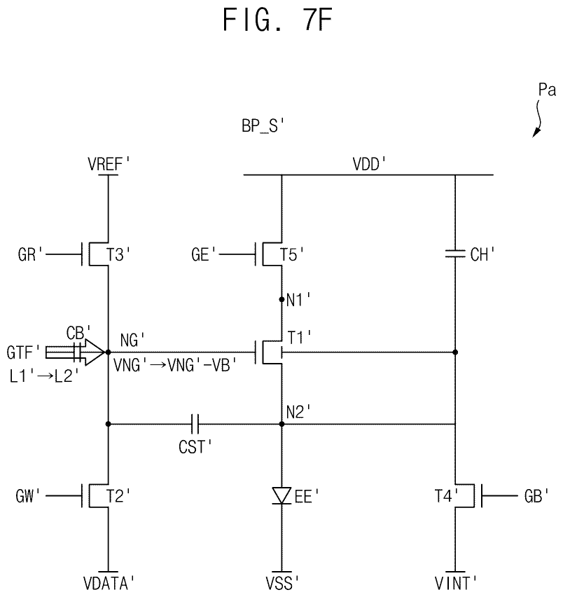

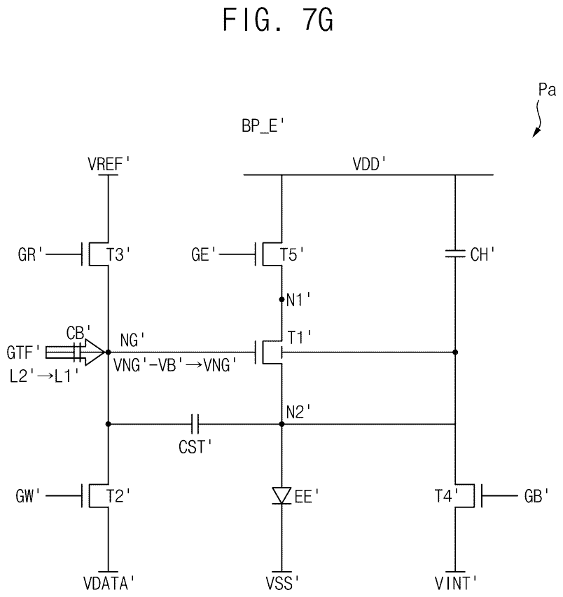

FIG. 7A is a circuit diagram showing the pixel circuit Pa of FIG. 5 operating in the first time period TP1′ of FIG. 6.

Referring to FIG. 5-7A, the reference voltage transistor T3′ may be turned on in response to the reference voltage gate signal GR′ having the high level. The reference voltage transistor T3′ may apply the reference voltage VREF′ to the gate electrode of the driving transistor T1′. The voltage of the gate electrode of the driving transistor T1′ may maintain the reference voltage VREF′ during the first time period TP1′.

FIG. 7B is a circuit diagram showing the pixel circuit Pa of FIG. 5 operating in a second time period TP2′ of FIG. 6.

Referring to FIG. 5-7B, the reference voltage transistor T3′ may be turned on in response to the reference voltage gate signal GR′ having the high level, and the anode initialization transistor T4′ may be turned on in response to the anode initialization gate signal GB′ having the high level. The reference voltage transistor T3′ may apply the reference voltage VREF′ to the gate electrode of the driving transistor T1′, and the anode initialization transistor T4′ may apply the initialization voltage VINT′ to the anode electrode. Therefore, the voltage of the second electrode of the driving transistor T1′ may be VINT′.

FIG. 7C is a circuit diagram showing the pixel circuit Pa of FIG. 5 operating in the third time period TP3′ of FIG. 6.

Referring to FIG. 5-7C, the reference voltage transistor T3′ may be turned on in response to the reference voltage gate signal GR′ having the high level, and the emission transistor T5′ may be turned on in response to the emission gate signal GE′ having the high level. The first driving voltage VDD′ may be applied to the second node N2′ through the emission transistor T5′ and the driving transistor T1′. The voltage of the second electrode of the driving transistor T1′ may increase to a voltage that is obtained by subtracting a threshold voltage VTH′ of the driving transistor T1′ from the initialization voltage VINT′. That is, the voltage of the second electrode of the driving transistor T1′ may increase from VINT′ to VREF′-VTH′. Because the voltage of the gate electrode of the driving transistor T1′ is VREF′, the storage capacitor CST′ may store VTH′ which is the threshold voltage of the driving transistor T1′. Therefore, the threshold voltage of the driving transistor T1′ may be compensated.

FIG. 7D is a circuit diagram showing the pixel circuit Pa of FIG. 5 operating in the fourth time period TP4′ of FIG. 6.

Referring to FIG. 5-7D, the data write transistor T2′ may be turned on in response to the data write gate signal GW′ having the high level.

The data write transistor T2′ may apply the data voltage VDATA′ to the gate electrode of the driving transistor T1′.

FIG. 7E is a circuit diagram showing the pixel circuit Pa of FIG. 5 operating the an emission period EP′ of FIG. 6.

Referring to FIG. 5-7E, the emission transistor T5′ may be turned on in response to the emission gate signal GE′ having the high level.

The driving current ID′ may flow in an order of the emission transistor T5′ and the driving transistor T1′ and may be applied to the light emitting element EE′. The light emitting element EE′ may emit the light based on the driving current ID′. An intensity of the driving current ID′ may be determined based on a level of the data voltage VDATA′. A brightness of the light emitting element EE′ may be determined based on an intensity of the driving current ID′.

FIG. 7F is a circuit diagram showing the pixel circuit Pa of FIG. 5 operating at the starting point BP_S′ of a boosting period BP′ of FIG. 6. FIG. 7G is a circuit diagram showing the pixel circuit Pa of FIG. 5 operating at the ending point BP_E′ of the boosting period BP′ of FIG. 6.

Referring to FIG. 5-7F, even in the non-emission period NEP′ where the driving current ID′ does not flow to the light emitting element EE′ and the light emitting element EE′ does not emit the light, the driving transistor T1′ may be turned on based on the voltage of the gate electrode of the driving transistor T1′. This is because the storage capacitor CST′ stores a voltage corresponding to the data voltage VDATA′. When the driving transistor T1 maintains a turned-on state, the driving transistor T1 may be further deteriorated. Therefore, the non-emission period NEP′ includes the boosting period BP′, so that the deterioration of the driving transistor T1′ may be prevented.

When the gate control signal GTF′ is changed from the first level L1′ to the second level L2′ at the starting point BP_S′ of the boosting period BP′, the voltage of the gate electrode of the driving transistor T1′ may decrease by the boosting voltage VB′ by the boost capacitor CB′. That is, the voltage of the gate electrode of the driving transistor T1′ may decrease from VNG′ to VNG′-VB′. When the voltage of the gate electrode of the driving transistor T1′ decrease by the boosting voltage VB′, the driving transistor T1′ may be turned off. In order for the driving transistor T1′ to be turned off, a magnitude of the boosting voltage VB′ may be sufficiently large.

In the boosting period BP′, the gate control signal GTF′ may maintain the second level L2′. Because the gate control signal GTF′ maintains the second level L2′, the driving transistor T1′ may maintain a turn-off state, and the deterioration of the driving transistor T1′ may be prevented.

When the gate control signal GTF′ is changed from the second level L2′ to the first level L1′ at the ending point BP_E′ of the boosting period BP′, the voltage of the gate electrode of the driving transistor T1′ may increase by the boosting voltage VB′ by the boost capacitor CB′. That is, the voltage of the gate electrode of the driving transistor T1 may increase from VNG′-VB′ to VNG′. When the voltage of the gate electrode of the driving transistor T1′ increases by the boosting voltage VB′, the driving transistor T1′ may be turned on.

Because the voltage of the gate electrode of the driving transistor T1′ before (e.g., immediately before) the starting point BP_S′ of the boosting period BP′ is VNG′ and the voltage of the gate electrode of the driving transistor T1 after (e.g., immediately after) the ending point BP_E′ of the boosting period BP′ is VNG′, the voltage of the gate electrode of the driving transistor T1′ before (e.g., immediately before) the starting point BP_S′ of the boosting period BP′ may be equal to the voltage of the gate electrode of the driving transistor T1′ after (e.g., immediately after) the ending point BP_E′ of the boosting period BP′. Therefore, even if the frame period FP′ includes the boosting period BP′, the voltage of the gate electrode of the driving transistor T1′ may be the same based on the before and after the boosting period BP′.

As such, the pixel circuit Pa may include the boost capacitor CB′ including the first electrode receiving the gate control signal GTF′ and the second electrode connected to the gate electrode of the driving transistor T1′. The voltage of the gate electrode of the driving transistor T1′ may be changed based on the gate control signal GTF′ in the boosting period BP′ included in the non-emitting period NEP′, and the driving transistor T1′ may be turned off in the boosting period BP′. Accordingly, the deterioration of the driving transistor T1′ may be prevented.

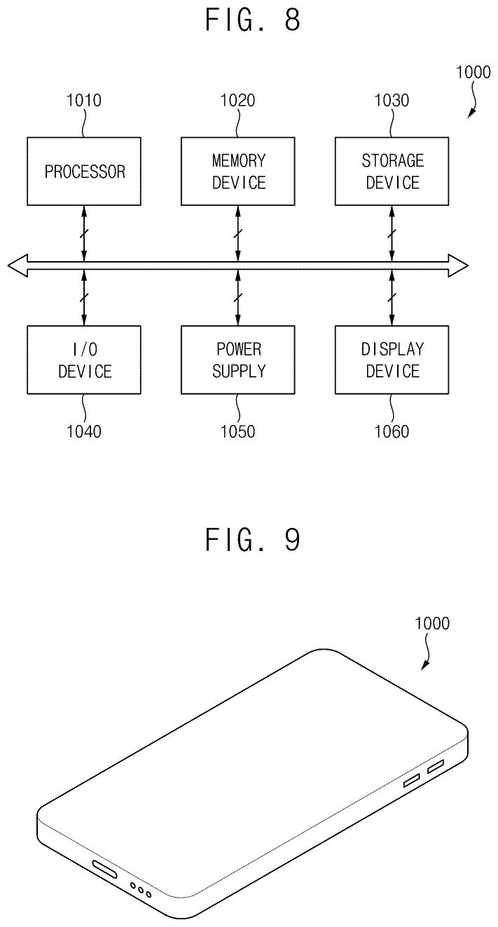

FIG. 8 is a block diagram showing an electronic device 1000. FIG. 9 is a diagram showing an embodiment in which an electronic device 1000 of FIG. 8 is implemented as a smart phone.

Referring to FIGS. 8 and 9, the electronic device 1000 may include a processor 1010, a memory device 1020, a storage device 1030, an input/output (I/O) device 1040, a power supply 1050, and a display device 1060. The display device 1060 may be the display device 10 of FIG. 1. In addition, the electronic device 1000 may further include a plurality of ports for communicating with a video card, a sound card, a memory card, a universal serial bus (USB) device, other electronic device, and/or the like.

In one or more embodiments, as illustrated in FIG. 9, the electronic device 1000 may be implemented as the smart phone. However, the electronic device 1000 is not limited thereto. For example, the electronic device 1000 may be implemented as a cellular phone, a video phone, a smart pad, a smart watch, a tablet PC, a car navigation system, a computer monitor, a laptop, a head mounted display (HMD) device, and the like.

The processor 1010 may perform various computing functions. The processor 1010 may be a micro-processor, a central processing unit (CPU), an application processor (AP), and/or the like. The processor 1010 may be coupled to other components via an address bus, a control bus, a data bus, and/or the like. Further, the processor 1010 may be coupled to an extended bus such as a peripheral component interconnection (PCI) bus.

The memory device 1020 may store data for operations of the electronic device 1000. For example, the memory device 1020 may include at least one nonvolatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, and/or the like and/or at least one volatile memory device such as a dynamic random access memory (DRAM) device, a static random access memory (SRAM) device, a mobile DRAM device, and/or the like.

The storage device 1030 may include a solid state drive (SSD) device, a hard disk drive (HDD) device, a CD-ROM device, and/or the like.

The I/O device 1040 may include an input device such as a keyboard, a keypad, a mouse device, a touch-pad, a touch-screen, and/or the like, and an output device such as a printer, a speaker, and the like. In one or more embodiments, the I/O device 1040 may include the display device 1060.

The power supply 1050 may provide power for operations of the electronic device 1000.

The display device 1060 may be connected to other components through buses or other communication links.

The present disclosure may be applied to any display device and any electronic device including the touch panel. For example, the present disclosure may be applied to a mobile phone, a smart phone, a tablet computer, a digital television (TV), a 3D TV, a personal computer (PC), a home appliance, a laptop computer, a personal digital assistant (PDA), a portable multimedia player (PMP), a digital camera, a music player, a portable game console, a navigation device, etc.

The foregoing is illustrative of the present disclosure and is not to be construed as limiting thereof. Although a few embodiments of the present disclosure have been described, those skilled in the art will readily appreciate that many modifications are possible in the embodiments without materially departing from the novel teachings and scope of the present disclosure. Accordingly, all such modifications are intended to be included within the scope of the present disclosure as defined in the claims and their equivalents. In the claims, means-plus-function clauses are intended to cover the structures described herein as performing the recited function and not only structural equivalents but also equivalent structures. Therefore, it is to be understood that the foregoing is illustrative of the present disclosure and is not to be construed as limited to the specific embodiments disclosed, and that modifications to the embodiments, as well as other embodiments, are intended to be included within the scope of the appended claims and their equivalents. The present disclosure is defined by the following claims, with equivalents of the claims to be included therein.

What is claimed is:

1. A pixel circuit comprising:
a light emitting element;
a driving transistor configured to apply a driving current to the light emitting element;
a storage capacitor comprising a first electrode connected to a gate electrode of the driving transistor and a second electrode; and
a boost capacitor comprising a first electrode configured to receive a gate control signal and a second electrode connected to the gate electrode of the driving transistor,
wherein the gate control signal is changed from a first level to a second level at a starting point of a boosting period in a non-emission period, and is changed from the second level to the first level at an ending point of the boosting period.

2. The pixel circuit of claim 1, wherein, when the gate control signal is changed from the first level to the second level, a voltage of the gate electrode of the driving transistor is changed by a boosting voltage corresponding to a difference between the first level and the second level, and the driving transistor is turned off based on a threshold voltage of the driving transistor.

3. The pixel circuit of claim 2, wherein, when the gate control signal is changed from the first level to the second level or from the second level to the first level, a voltage of the gate electrode of the driving transistor is changed by the boosting voltage.

4. The pixel circuit of claim 3, wherein a voltage of the gate electrode of the driving transistor immediately before the starting point of the boosting period is equal to a voltage of the gate electrode of the driving transistor immediately after the ending point of the boosting period.

5. The pixel circuit of claim 3, wherein, when the driving transistor is a P-type transistor, the first level is lower than the second level.

6. The pixel circuit of claim 5, wherein, when the gate control signal is changed from the first level to the second level, the voltage of the gate electrode of the driving transistor increases by the boosting voltage.

7. The pixel circuit of claim 6, wherein, when the gate control signal is changed from the second level to the first level, the voltage of the gate electrode of the driving transistor decreases by the boosting voltage.

8. The pixel circuit of claim 5, wherein the driving transistor comprises the gate electrode connected to a gate node, a first electrode connected to a first node, and a second electrode connected to a second node,
wherein the storage capacitor comprises the first electrode connected to the gate node and the second electrode configured to receive a first driving voltage,
wherein the boost capacitor comprises the first electrode configured to receive the gate control signal and the second electrode connected to the gate node, and
wherein the light emitting element comprises an anode electrode and a cathode electrode configured to receive a second driving voltage.

9. The pixel circuit of claim 8, further comprising:
a data write transistor comprising a gate electrode configured to receive a data write gate signal, a first electrode configured to receive a data voltage, and a second electrode connected to the first node;
a compensation transistor comprising a gate electrode configured to receive the data write gate signal, a first electrode connected to the second node, and a second electrode connected to the gate node;
a data initialization transistor comprising a gate electrode configured to receive a data initialization gate signal, a first electrode configured to receive an initialization voltage, and a second electrode connected to the gate node;
a first emission transistor comprising a gate electrode configured to receive an emission signal, a first electrode configured to receive the first driving voltage, and a second electrode connected to the first node;
a second emission transistor comprising a gate electrode configured to receive the emission signal, a first electrode connected to the second node, and a second electrode connected to the anode electrode; and
an anode initialization transistor including a gate electrode configured to receive an anode initialization gate signal, a first electrode configured to receive the initialization voltage, and a second electrode connected to the anode electrode.

10. The pixel circuit of claim 9, wherein the non-emission period does not comprise a turn-on voltage period of the emission signal, and an emission period comprises the turn-on voltage period of the emission signal.

11. The pixel circuit of claim 9, wherein a non-boosting period in the non-emission period comprises a turn-on voltage period of the data write gate signal, a turn-on voltage period of the data initialization gate signal, a turn-on voltage period of the emission signal, and a turn-on voltage period of the anode initialization gate signal.

12. The pixel circuit of claim 3, wherein, when the driving transistor is an N-type transistor, the first level is higher than the second level.

13. The pixel circuit of claim 12, wherein, when the gate control signal is changed from the first level to the second level, the voltage of the gate electrode of the driving transistor decreases by the boosting voltage.

14. The pixel circuit of claim 13, wherein, when the gate control signal is changed from the second level to the first level, the voltage of the gate electrode of the driving transistor increases by the boosting voltage.

15. The pixel circuit of claim 12, wherein the driving transistor comprises the gate electrode connected to a gate node, a first electrode connected to a first node, a second electrode connected to a second node, and a back gate electrode connected to the second node,
wherein the storage capacitor comprises the first electrode connected to the gate node and the second electrode connected to the second node,
wherein the boost capacitor comprises the first electrode configured to receive the gate control signal and the second electrode connected to the gate node, and
wherein the light emitting element comprises an anode electrode and a cathode electrode configured to receive a second driving voltage.

16. The pixel circuit of claim 15, further comprising:
a data write transistor comprising a gate electrode configured to receive a data write gate signal, a first electrode configured to receive a data voltage, and a second electrode connected to the gate node;
a reference voltage transistor comprising a gate electrode configured to receive a reference voltage gate signal, a first electrode configured to receive a reference voltage, and a second electrode connected to the gate node;
an anode initialization transistor comprising a gate electrode configured to receive an anode initialization gate signal, a first electrode configured to receive an initialization voltage, and a second electrode connected to the anode electrode;
an emission transistor comprising gate electrode configured to receive an emission gate signal, a first electrode configured to receive a first driving voltage, and a second electrode connected to the first node; and
a hold capacitor comprising a first electrode configured to receive the first driving voltage and a second electrode connected to the second node.

17. The pixel circuit of claim 16, wherein an emission period comprises a turn-on voltage period of the emission gate signal.

18. The pixel circuit of claim 16, wherein a non-boosting period in the non-emission period comprises a turn-on voltage period of the data write gate signal, a turn-on voltage period of the reference voltage gate signal, a turn-on voltage period of the anode initialization gate signal, and a turn-on voltage period of the emission gate signal.

19. A display device comprising:
a display panel comprising a pixel circuit; and
a display panel driver configured to drive the display panel,
wherein the pixel circuit comprises:
a light emitting element;
a driving transistor configured to apply a driving current to the light emitting element;
a storage capacitor comprising a first electrode connected to a gate electrode of the driving transistor and a second electrode; and
a boost capacitor comprising a first electrode configured to receive a gate control signal and a second electrode connected to the gate electrode of the driving transistor, and
wherein the gate control signal is changed from a first level to a second level at a starting point of a boosting period in a non-emission period, and is changed from the second level to the first level at an ending point of the boosting period.

20. The display device of claim 19, wherein, when the gate control signal is changed from the first level to the second level, a voltage of the gate electrode of the driving transistor is changed by a boosting voltage corresponding to a difference between the first level and the second level, and the driving transistor is turned off based on a threshold voltage of the driving transistor.

21. An electronic device comprising a display device, the display device comprising:
a display panel comprising a pixel circuit; and
a display panel driver configured to drive the display panel,
wherein the pixel circuit comprises:
a light emitting element;
a driving transistor configured to apply a driving current to the light emitting element;
a storage capacitor comprising a first electrode connected to a gate electrode of the driving transistor and a second electrode; and
a boost capacitor comprising a first electrode configured to receive a gate control signal and a second electrode connected to the gate electrode of the driving transistor,
wherein the gate control signal is changed from a first level to a second level at a starting point of a boosting period in a non-emission period, and is changed from the second level to the first level at an ending point of the boosting period, and
wherein, when the driving transistor is a P-type transistor, the first level is lower than the second level.

22. The electronic device of claim 21, wherein the electronic device comprises a cellular phone, a video phone, a smart pad, a smart watch, a tablet PC, a car navigation system, a computer monitor, a laptop, or a head mounted display (HMD) device.
